(19) United States
(12) Patent Application Publication
(10) Pub. No.: US 2007/0019259 A1
(43) Pub. Date: Jan. 25, 2007

(54) IMAGE FORMING APPARATUS AND IMAGE FORMING METHOD

(76) Inventor: Hyun-suk Lee, Suwon-si (KR)

Correspondence Address: STANZIONE & KIM, LLP, 919 18TH STREET, N.W., SUITE 440, WASHINGTON, DC, 20006, US

(21) Appl. No.: 11/380,990

(22) Filed: May 1, 2006

(30) Foreign Application Priority Data
Jul. 21, 2005 (KR) 2005-66462

(51) Int. Cl. G03F 3/10

(52) U.S. Cl. 358/527; 358/538

(57) ABSTRACT

An image forming method used in an image forming apparatus to print an image based on printing data. The method includes displaying a first area box that corresponds to a sheet of recording medium, and a second area box that corresponds to a part of the image or a position of the part of the image on the sheet of recording medium, selecting the part of the image or the position of the part of the image on the sheet of recording medium through the first area box and the second area box, processing the printing data that corresponds to the selected part of the image, and outputting the processed printing data to the selected position of the sheet of recording medium. Thus, the image forming method and apparatus can conveniently print an image in a variety of manners according to a user taste or preference.

### CROSS-REFERENCE TO RELATED APPLICATIONS

This application claims the benefit of Korean Patent Application No. 2005-66462, filed on Jul. 21, 2005, in the Korean Intellectual Property Office, the disclosure of which is incorporated herein by reference in its entirety.

### BACKGROUND OF THE INVENTION

1. Field of the Invention

The present general inventive concept relates to an image forming apparatus and an image forming method, and more particularly, to an image forming apparatus and an image forming method, in which an image can be conveniently printed in a variety of manners according to a taste or preference of a user.

2. Description of the Related Art

A conventional image forming apparatus receives printing data that corresponds to a picture, a photograph, or the like from an image processing apparatus such as a computer system, a digital camera, etc., or from an image storing apparatus such as a universal serial bus (USB) memory, etc. The image forming apparatus then applies a predetermined image processing operation to the received printing data. The image forming apparatus forms an image on a recording medium such as paper or the like based on the processed printing data, thereby printing an image. Here, the image forming apparatus includes a printer, a multi-function printer, etc.

Occasionally, the image forming apparatus is used to print only a portion of the image (i.e., a partial image) according to a user's selection. In this case, the conventional image forming apparatus is provided with a display unit for displaying the portion of the image to be printed. Thus, the image is enlarged/reduced or moved upward, downward, leftward and rightward according to a user's input, and the portion of the image to be printed is displayed within a limited display area of the display unit and then is set to be printed.

However, in the conventional image forming apparatus, the image is moved upward, downward, leftward and rightward while being enlarged or reduced, so that it is inconvenient for the user to set the portion of the image to be printed (i.e., the partial image), because an entire image is not displayed to the user. Further, in the conventional image forming apparatus, the image is enlarged to set the portion of the image to be printed, and reduced again as necessary, so that the conventional image forming apparatus is required to repeatedly perform the image processing operation for displaying the image on the display unit. The image processing operation may cause the image forming operation to be delayed.

In an effort to solve these problems, a conventional printer and a conventional printing method is described in Japanese Patent First Publication No. 2004-009335, in which a display unit is provided to display an image such that a partial image is selected from the displayed image by manipulating a movable rectangular frame, thereby printing an image. According to this printer and printing method, the rectangular frame is used in selecting a partial image, so that it is easier to select the portion of the image to be printed from the entire image. Further, there is little extra burden resulting from the image processing operation performed when enlarging or reducing the image. Also, the image may be formed with less delay.

However, in the conventional printer and printing method described above, the portion of the image to be printed is selected within the entire image without regard to information about paper or recording medium, so that a margin of the paper is not considered at all when the portion of the image to be printed (i.e., the partial image) is printed on the paper. In other words, in the conventional printer and printing method, a position and a size of the partial image is not set with respect to the paper, so that the partial image may not be printed in a manner desired by the user.

Further, in the conventional image forming apparatus and image forming method, the partial image is selected from just one image and then printed, so that it is difficult to print in a variety of manners desired by the user, for example, combining a plurality of partial images or repeatedly arranging the same image.

### SUMMARY OF THE INVENTION

Accordingly, the present general inventive concept provides an image forming apparatus and an image forming method, in which an image can be conveniently printed in a variety of manners according to a user taste or preference.

Additional aspects of the general inventive concept will be set forth in part in the description which follows and, in part, will be obvious from the description, or may be learned by practice of the general inventive concept.

The foregoing and/or other aspects of the present general inventive concept may be achieved by providing an image forming method used in an image forming apparatus to print an image based on printing data, the method comprising displaying a first area box that corresponds to a sheet of recording medium, and a second area box that corresponds to a selected part of the image or a selected position of the part of the image on the sheet of recording medium, selecting the part of the image or the position of the part of the image on the sheet of the recording medium using the first area box and the second area box, processing the printing data that corresponds to the selected part of the image, and outputting the processed printing data to the selected position of the sheet of recording medium.

The method may further comprise reducing or enlarging the first area box and the second area box according to an input command.

The input command may comprise a selection of one or more of a plurality of keys provided on a control panel (OPE) or a touch screen of the image forming apparatus.

The method may further comprise moving the first area box and the second area box with respect to the image based on the printing data according to an input command.

The input command may comprise a selection of one or more of a plurality of keys provided on a control panel (OPE) or a touch screen of the image forming apparatus.

The method may further comprise rotating the first area box and the second area box with respect to the image based on the printing data according to an input command.

The selecting of the part of the image and the position of the part of the image may comprise selecting a plurality of positions on one sheet of recording medium on which the selected part of the image is printed.

The selecting of the part of the image and the position of the part of the image comprises selecting at least one part of each of a plurality of images. The selecting of the part of the image and the position of the part of the image may comprise selecting a plurality of positions to correspond to the selected parts of the plurality of images on one sheet of recording medium.

The selecting of the part of the image and the position of the part of the image may be performed using either of the first area box or the second area box.

The foregoing and/or other aspects of the present general inventive concept may also be achieved by providing a method of an image forming apparatus, the method comprising displaying an image, a first area box movable to indicate a portion of the image to be printed on a sheet of recording medium, and a second area box movable to indicate a position on the sheet of recording medium at which the portion of the image is to be printed, and enabling manipulation of the first and second area boxes.

The foregoing and/or other aspects of the present general inventive concept may also be achieved by providing an image forming apparatus comprising a display unit to display an image to be printed based on printing data, an input unit to receive an input about printing the image, an image processor to process the printing data, a printer to print the image based on the processed printing data on a sheet of recording medium, and a controller that controls the display unit to display a first area box that corresponds to the sheet of recording medium and a second area box that corresponds to a part of the image or a position of the part of the image on the sheet of recording medium, receives a selection of the part of the image or the position of the part of the image on the sheet of recording medium selected by the first area box and the second area box from the input unit, and controls the image processor and the printer to process the printing data that corresponds to the selected part of the image, and outputs the processed printing data to the selected position of the sheet of recording medium.

The controller may control the display unit to reduce or enlarge the first area box and the second area box according to an input command.

The input unit may comprise a control panel (OPE) or a touch screen having a plurality of keys, and the controller may control the display unit to reduce or enlarge the first area box and the second area box according to the input command which may comprise a selection of one or more of the plurality of keys.

The controller may control the display unit to move the first area box and the second area box according to an input command.

The input unit may comprise a control panel (OPE) or a touch screen having a plurality of keys, and the controller may control the display unit to move the first area box and the second area box according to the input command which may comprise a selection of one or more of the plurality of keys.

The controller may control the display unit to rotate the first area box and the second area box according to an input command.

The input unit may comprise a control panel (OPE) or a touch screen having a plurality of keys, and the controller may control the display unit to rotate the first area box and the second area box according to the input command which may comprise a selection of one or more of the plurality of keys.

The controller may receive a command to select a plurality of positions on one sheet of recording medium, on which the selected part of the image is printed.

The controller may receive a command to select at least one part from each of a plurality of images.

The controller may receive a command to select a plurality of positions in one sheet of recording medium to correspond to the selected parts of the plurality of images.

The controller may control the selected part of the image or the selected position of the part of the image on the sheet of recording medium through either of the first area box or the second area box.

The foregoing and/or other aspects of the present general inventive concept may also be achieved by providing an image forming apparatus, comprising a display unit to display an image, a first area box movable to indicate a portion of the image to be printed on a sheet of recording medium, and a second area box movable to indicate a position on the sheet of recording medium at which the indicated portion of the image is to be printed, and an input unit to enable manipulation of the first and second area boxes.

The foregoing and/or other aspects of the present general inventive concept may also be achieved by providing an apparatus usable with an image forming device, the apparatus comprising a display unit to display an image, a first selector to select a portion of the image to be printed on a sheet of recording medium, and a second selector to select a position within the sheet of recording medium at which the selected portion of the image is to be printed, and an input unit to enable manipulation of the first and second selectors.

The foregoing and/or other aspects of the present general inventive concept may also be achieved by providing a user interface, comprising an image, a first area box movable to indicate a portion of the image to be printed on a sheet of recording medium, and a second area box movable to indicate a position within the sheet of recording medium at which the indicated portion of the image is to be printed.

The foregoing and/or other aspects of the present general inventive concept may also be achieved by providing a computer readable medium containing executable code to control an image forming apparatus having a display unit and an input unit, the medium comprising executable code to control the display unit to display an image, a first area box movable to indicate a portion of the image to be printed on a sheet of recording medium, and a second area box movable to indicate a position on the sheet of recording medium at which the indicated portion of the image is to be printed, and executable code to control the input unit to receive a command to manipulate of the first and second area boxes.

### BRIEF DESCRIPTION OF THE DRAWINGS

These above and/or other aspects of the present general inventive concept will become apparent and more readily appreciated from the following description of the embodiments, taken in conjunction with the accompany drawings of which:

FIG. 1 is a control block diagram illustrating an image forming apparatus according to an embodiment of the present general inventive concept;

FIG. 2 illustrates a mark used to print an image by selecting a partial image and determining a position to be printed on a recording medium according to an embodiment of the present general inventive concept;

FIG. 3 illustrates a mark used to print an image by selecting a partial image and determining a position to be printed on a recording medium according to another embodiment of the present general inventive concept;

FIG. 4 illustrates a mark used to print an image by selecting a partial image and determining a position to be printed on a recording medium according to another embodiment of the present general inventive concept;

FIG. 5 illustrates a control panel of an input unit of the image forming apparatus of FIG. 1 according to an embodiment of the present general inventive concept; and

FIG. 6 is a control flowchart illustrating an image forming method according to another embodiment of the present general inventive concept.

### DETAILED DESCRIPTION OF THE PREFERRED EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

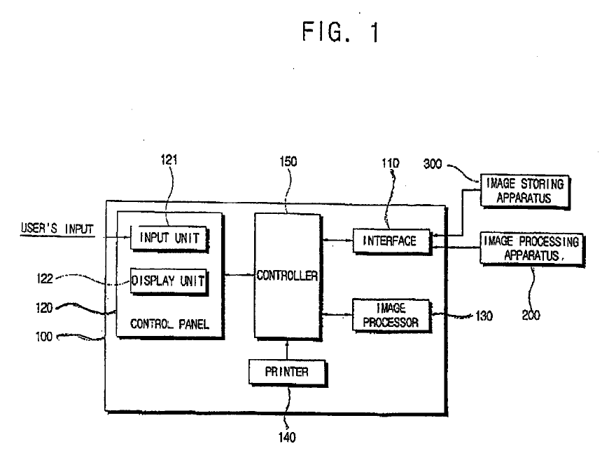

FIG. 1 is a control block diagram illustrating an image forming apparatus 100 according to an embodiment of the present general inventive concept. The image forming apparatus 100 receives printing data that corresponds to a picture, a photograph, or the like from an image processing apparatus 200 (e.g., a computer system, a digital camera, etc.), or from an image storing apparatus 300 (e.g., a USB memory, etc.). The image forming apparatus 100 then applies a predetermined image processing operation to the received printing data. Then, the image forming apparatus 100 forms an image on a recording medium such as paper or the like based on the processed printing data, thereby printing an image. More specifically, the image forming apparatus 100 displays a mark to allow a user to select a part of the image and to determine a position of the selected part of the image with respect to the recording medium or sheet of recording medium. Therefore, the image forming apparatus 100 processes the printing data based on the selected part of the image and the determined position, thereby printing the image.

As illustrated in FIG. 1, the image forming apparatus 100 according to an embodiment of the present general inventive concept includes an interface 110, a control panel 120, an image processor 130, a printer 140, and a controller 150. The interface 110 performs data communication with and receives the printing data from the image processing apparatus 200 or the image storing apparatus 300. Here, the interface 110 employs one or more predetermined protocols to communicate data with the image processing apparatus 200 and the image storing apparatus 300. The interface 110 may include a network card, a USB connector, etc. according to the protocols used to communicate with the image processing apparatus 200 and the image storing apparatus 300.

The control panel 120 displays the image to be printed, and receives an input from the user. The control panel 120 includes an input unit 121 and a display unit 122. The display unit 122 is controlled by the controller 150 to convert the printing data received through the interface 110 to have a predetermined format, thereby displaying a corresponding image to the user. Further, the display unit 122 displays the mark according to the control of the controller 150, thereby allowing the user to select the part of the image and to determine the position of the selected part of the image with respect to the recording medium (or the sheet of recording medium). Also, the display unit 122 may display a message to indicate to the user an operating state of the image forming apparatus 100, a message to request the user to perform a selecting operation, etc. Here, the display unit 122 may include a thin film transistor liquid crystal display (TFT LCD), and a driver (not shown) to drive the TFT LCD. Alternatively, the display unit 122 may include other types of displays.

The input unit 121 may include a plurality of keys, and receives an input from the user, thereby transmitting the input to the controller 150. The input unit 121 receives the input from the user to control the mark when the mark is displayed to enable the user to select the part of the image to be printed and to determine the position of the selected part of the image with respect to the recording medium (or the sheet of recording medium). Here, the input unit 121 may be implemented using, for example, a control panel (OPE) having a plurality of keys.

The image processor 130 processes the printing data to be printed based on the selected part of the image and the determined position according to the control of the controller 150. Here, the image processor 130 can be implemented using, for example, an image processor chip. The printer 140 prints the image based on the printing data processed by the image processor 130 on the recording medium (e.g., paper) according to the control of the controller 150. The printer 140 can print the image using an inkjet method, a laser method, etc.

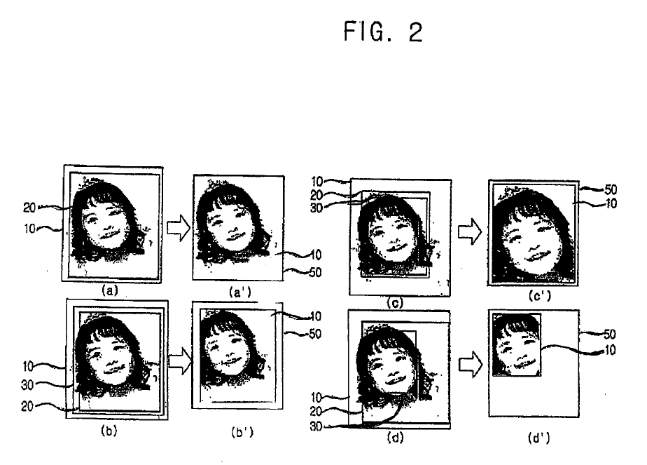

The controller 150 controls overall operation the image forming apparatus 100. The controller 150 will now be described with reference to FIGS. 2 through 4. FIGS. 2 through 4 illustrate the mark used to print an image 10 by selecting a partial image and determining a position of the partial image to be printed on a recording medium 50 (i.e., a sheet of recording medium)according to the various embodiments of the present general inventive concept. As illustrated in a mask (a) of FIG. 2, the controller 150 illustrated in FIG. 1 controls the display unit 122 to display a first area box 20 to be overlapped with the image 10 based on the received printing data, in which the first area box 20 is provided to enable the user to select a part 20 of the image 10 as a partial image to be printed. The first area box 20 corresponds to the partial image and the selected part of the image 10 to be printed. As illustrated in masks (c) and (d) of FIG. 2, when the user enters a command to move, enlarge, or reduce the first area box 20 through the input unit 121 illustrated in FIG. 1, the controller 150 controls the display unit 122 to display the first area box 20 being moved, enlarged, or reduced according to the command. Here, the controller 150 processes the printing data so that the selected part of the image 10 selected by the first area box 20 is printed on the recording medium 50. Further, as illustrated in masks (a′), (b′), (′c), and (d′) of FIG. 2, the controller 150 controls the image processor 130 and the printer 140 to print the selected part 20 of the image 10 based on the processed printing data.

As illustrated in the mask (b) of FIG. 2, the controller 150 of FIG. 1 controls the display unit 122 to display a second area box 30 to be overlapped with the image 10, in which the second area box 30 is provided as a second partial image to enable the user to select a position of the selected part 20 of the image 10 (i.e., the partial image) with respect to the recording medium 50 (i.e., the sheet of the recording medium). According to the selected position, the second area box 30 is adjusted as the second partial image with respect to the partial image 20 and/or the image 10. As illustrated in the masks (c) and (d) of FIG. 2, when the user enters a command to move, enlarge, or reduce the second area box 30 through the input unit 121 of FIG. 1, the controller 150 controls the display unit 122 to display the second area box 30 being moved, enlarged, or reduced according to the command. Here, the controller 150 of FIG. 1 processes the printing data so that the part 20 of the image 10 selected by the first area box 20 is printed at the position determined by the second area box 30 on the recording medium 50. As illustrated in the masks (b′), (c′), and (d′) of FIG. 2, the controller 150 controls the image processor 130 and the printer 140 to print the selected part 30 of the image 10 based on the processed printing data.

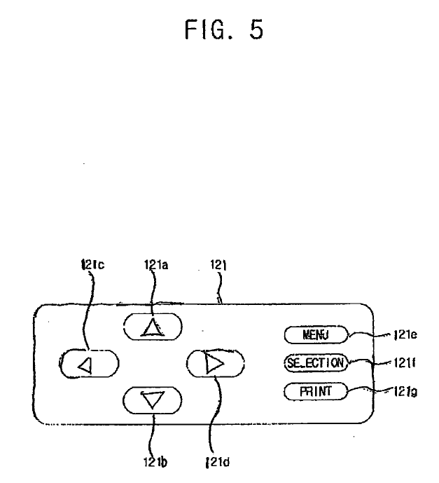

FIG. 5 illustrates the input unit 121 of the control panel 120 of the image forming apparatus 100 of FIG. 1 according to an embodiment of the present general inventive concept. The input unit 121 receives the commands to enlarge, reduce, and move the first and second area boxes 20 and 30 according to a combination of the plurality of keys provided on the control panel 120. For example, the input unit 121 may include up, down, left, and right keys 121a, 121b, 121c, and 121d. The input unit 121 may further include a menu key 121 e, a selection key 121f, and a print key 121g. Each of the up, down, left, and right keys 121a, 121b, 121c, and 121d may be set to move the second area box 30. When the print key 121g is pressed, each of the up, down, left and right keys 121a, 121b, 121c, and 121d may be re-set to move the first area box 20. When the menu key 121e is pressed, each of the up, down, left and right keys 121a, 121b, 121c, and 121d may be set to adjust the size of the first and second area boxes 20 and 30. Further, when the size adjustment and the movement of the first and second area boxes 20 and 30 is completed, the input unit 121 receives a command to determine the part 20 of the image 10 to be printed and the position 30 through the selection key 121f.

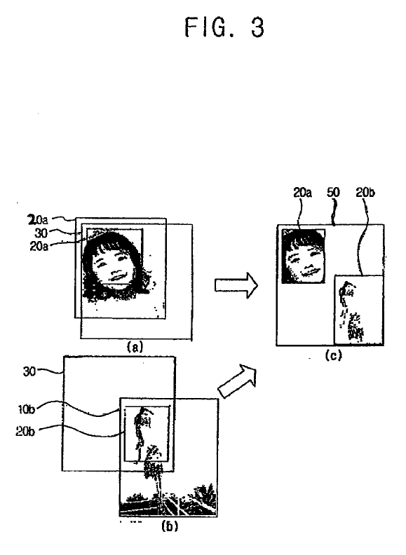

As illustrated in the masks (a), (b), and (c) of FIG. 3, when the user selects one or more parts 20a and 20b of a plurality of images 10a and 10b and selects their respective positions 30 through the input unit 121, the controller 150 can control the image processor 130 and the printer 140 to process the printing data that corresponds to the selected parts 20a and 20b of the images 10a and 10b to be printed on one sheet of recording medium 50 at the respective positions 30 (FIG. 3(c)).

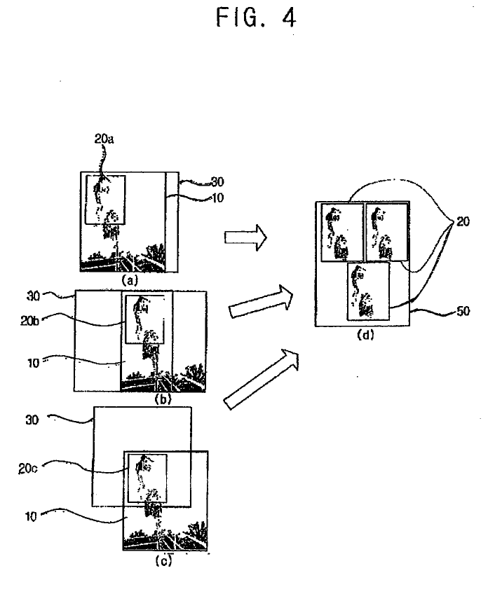

Further, as illustrated in the masks (a), (b), (c), and (d) of FIG. 4, when the user selects a plurality of parts 20a, 20b, and 20c of the same image 10 and arranges the selected parts 20a, 20b, and 20c of the image 10 at a plurality of positions 30 through the input unit 121, the controller 150 can control the image processor 130 and the printer 140 to process the printing data that corresponds to the selected parts 20a, 20b and 20c to be printed at the plurality of positions on one sheet of recording medium 50 (FIG. 4(d)).

Also, when the user rotates at least one of the first and second area boxes 20 and 30 using the input unit 121, the controller 150 can control the display unit 122 to rotate the first and second area boxes 20 and 30 with respect to the image 10 according to the user's input. In this case, the controller 150 can control the image processor 130 and the printer 140 to process the printing data that corresponds to the selected part 20 of the image 10 and the selected position 30 on the recording medium 50.

According to an embodiment of the present general inventive concept, the controller 150 may be achieved by a software program operated by a microprocessor such as a central processing unit (CPU). In this case, the image forming apparatus 100 includes a memory such as a flash memory to store the software program. Here, the software program may be properly programmed to the microprocessor, thereby performing the functions and the operations of the controller 150. More generally, the software program may be a computer readable medium containing executable code to perform the operations of the controller 150.

The present general inventive concept may also be embodied in a user interface having an image (e.g., the image 10) and the first and second area boxes 20 and 30. For example, the user interface may include a window with one or more tabs.

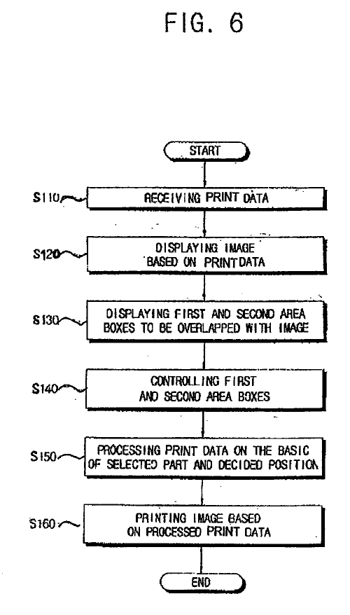

FIG. 6 is a control flowchart illustrating an image forming method according to another embodiment of the present general inventive concept. The image forming method of FIG. 6 may be performed by the image forming apparatus 100 of FIG. 1. Accordingly, the method of FIG. 6 is illustrated below with reference to FIGS. 1 through 6. At operation S110, the interface 110 of the image forming apparatus 100 receives the printing data from the image processing apparatus 200 or the image storing apparatus 300. At operation S120, the controller 150 controls the display unit 122 to display an image based on the printing data received through the interface 110. At operation S130, the controller 150 controls the display unit 122 to display the first and second area boxes (20 and 30 in FIGS. 2 to 4) to be overlapped with the image. At operation S140, the controller 150 receives the commands from the user through the input unit 121, and controls the display unit 122 to display the first and second area boxes (20 and 30 in FIGS. 2 to 4) that are moved, enlarged or reduced.

When the user enters a printing command after the user completes the movement and size adjustment of the first and second area boxes (20 and 30 in FIGS. 2 to 4), at operation S150 the controller 150 controls the image processor 130 to process the printing data based on the selected part of the image and the determined position of the selected part of the image with respect to the recording medium. When the image processor 130 completes the processing of the printing data, at operation S160 the controller 150 controls the printer 140 to print the image based on the processed printing data.

Although the embodiments of the present general inventive concept describe the control panel 120 including the display unit 122 and the input unit 121 as being included in the image forming apparatus 100, it should be understood that the control panel 120 including the display unit 122 and the input unit 121 may be included in an external device such as a host device. In this case, the user could manipulate the first and second area boxes 20 and 30 on a screen of the host device using, for example, a keyboard, a mouse, or another input device to select the part of the image to be printed and the position on the recording medium at which the selected part of the image is to be printed. The host device may then provide the image forming apparatus 100 via the interface 110 (see FIG. 1) with the printing data that corresponds to the selected part of the image and the selected position on the recording medium, instead of providing the image forming apparatus 100 with the printing data of the entire image.

As described above, the various embodiments of the present general inventive concept provides an image forming apparatus and an image forming method, in which an image can be conveniently printed in a variety of manners according to a user taste or preference.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A method of an image forming apparatus, the method comprising:
displaying an image, a first area box movable to indicate a portion of the image to be printed on a sheet of recording medium, and a second area box movable to indicate a position on the sheet of recording medium at which the indicated portion of the image is to be printed; and
enabling manipulation of the first and second area boxes.

2. The method according to claim 1, further comprising:
receiving printing data that corresponds to the indicated portion of the image to be printed and to process the received printing data; and
printing the processed printing data to the indicated position within the sheet of recording medium.

3. The method according to claim 1, wherein the displaying of the second area box comprises displaying a plurality of second area boxes movable to a plurality of positions on the sheet of recording medium such that the indicated portion of the image is printed at the plurality of positions on the sheet of recording medium.

4. The method according to claim 3, wherein:
the displaying of the image comprises displaying a plurality of images; and
the displaying of the first area box comprises displaying a plurality of first area boxes such that a plurality of portions of the plurality of images are selected to be printed to the plurality of positions on the sheet of recording medium.

5. The method according to claim 1, wherein the enabling of the manipulation of the first and second area boxes comprises enabling the first and second area boxes to be moved, size adjusted, and rotated.

6. An image forming apparatus, comprising:
a display unit to display an image, a first area box movable to indicate a portion of the image to be printed on a sheet of recording medium, and a second area box movable to indicate a position on the sheet of recording medium at which the indicated portion of the image is to be printed; and
an input unit to enable manipulation of the first and second area boxes.

7. The image forming apparatus according to claim 6, further comprising:
an image processor to receive printing data that corresponds to the indicated portion of the image to be printed and to process the received printing data; and
a printer to print the processed printing data to the indicated position within the sheet of recording medium.

8. The image forming apparatus according to claim 6, wherein the second area box includes a plurality of second area boxes movable to a plurality of positions on the sheet of recording medium such that the indicated portion of the image is printed at the plurality of positions on the sheet of recording medium.

9. The image forming apparatus according to claim 8, wherein:
the image comprises a plurality of images; and
the first area box comprises a plurality of first area boxes such that a plurality of portions of the images are selected to be printed to the plurality of positions on the sheet of recording medium.

10. The image forming apparatus according to claim 6, wherein the input unit enables the first and second area boxes to be moved, size adjusted, and rotated.

11. The image forming apparatus according to claim 6, wherein the display unit and the input unit are part of a control panel having an interface and a plurality of selection keys that are selectable by a user to manipulate the first and second boxes.

12. An image manipulation apparatus usable with an image forming device, comprising:
a display unit to display an image, a first selector to select a portion of the image to be printed on a sheet of recording medium, and a second selector to select a position within the sheet of recording medium at which the selected portion of the image is to be printed; and
an input unit to enable manipulation of the first and second selectors.

13. The image manipulation apparatus according to claim 12, wherein the first and second selectors comprise movable area boxes.

14. A user interface, comprising:
an image;
a first area box movable to indicate a portion of the image to be printed on a sheet of recording medium; and
a second area box movable to indicate a position within the sheet of recording medium at which the indicated portion of the image is to be printed.

15. The user interface according to claim 14, wherein the first area box selects a partial image and the second area box selects the position within the sheet of recording medium at which to print the partial image.

16. A computer readable medium containing executable code to control an image forming apparatus having a display unit and an input unit, the medium comprising:
executable code to control the display unit to display an image, a first area box movable to indicate a portion of the image to be printed on a sheet of recording medium, and a second area box movable to indicate a position on the sheet of recording medium at which the indicated portion of the image is to be printed; and
executable code to control the input unit to receive a command to manipulate the first and second area boxes.
